(19) United States
(12) Patent Application Publication
(10) Pub. No.: US 2024/0250212 A1
(43) Pub. Date: Jul. 25, 2024

(54) LIGHT-EMITTING DEVICE AND DISPLAY APPARATUS INCLUDING THE SAME

(71) Applicant: LG Display Co., Ltd., Seoul (KR)

(72) Inventors: Il-Soo KIM, Goyang-si (KR); Myungsoo HAN, Goyang-si (KR); Jung-Hun CHOI, Paju-si (KR); Hyowon KWON, Suwon-si (KR); Dongwon YANG, Seoul (KR)

(73) Assignee: LG Display Co., Ltd., Seoul (KR)

(21) Appl. No.: 18/397,741

(22) Filed: Dec. 27, 2023

(30) Foreign Application Priority Data
Jan. 20, 2023 (KR) 10-2023-0008471

(51) Int. Cl. H01L 33/32; H01L 25/16

(52) U.S. Cl. CPC H01L 33/32; H01L 25/167

(57) ABSTRACT

Disclosed is a light-emitting device including a light-emitting structure including a first semiconductor layer, an active layer, and a second semiconductor layer; a first electrode connected to the first semiconductor layer; and a second electrode connected to the second semiconductor layer, wherein an energy bandgap of the first semiconductor layer decreases as the first semiconductor layer extends away from the active layer.

### CROSS-REFERENCE TO RELATED APPLICATION

This application claims priority from Korean Patent Application No. 10-2023-0008471 filed on Jan. 20, 2023 in the Korean Intellectual Property Office, and all the benefits accruing therefrom under 35 U.S.C. 119, the contents of which in its entirety are herein incorporated by reference.

### BACKGROUND

### Technical Field

The present disclosure relates to a light-emitting device and a display apparatus including the same. More specifically, the present disclosure relates to a light-emitting device capable of operating at low current, and a display apparatus capable of displaying an image at a low gray-scale.

### Discussion of the Related Art

A flat panel display apparatus includes a liquid crystal display apparatus and an organic light-emitting display apparatus.

The organic light-emitting display apparatus has advantages such as improved luminous efficiency, a fast response speed, and a wide viewing angle compared to the liquid crystal display apparatus. However, since the organic light-emitting display apparatus includes an organic material, the organic light-emitting display apparatus is vulnerable to moisture and oxygen, and thus, a defective pixel may occur.

Recently, an inorganic light-emitting display apparatus using an inorganic light-emitting layer that is resistant to moisture and oxygen has been proposed. The inorganic light-emitting display apparatus in which an inorganic light-emitting diode having a size of 100 micrometers or smaller is disposed in each pixel is referred to as a micro-light-emitting diode (micro-LED) display apparatus.

### SUMMARY

A currently mass-produced inorganic light-emitting diode cannot operate in a low-current level due to a high potential barrier between a semiconductor layer and an electrode. Thus, the display apparatus cannot display an image at a low gray-scale level.

Therefore, in order to provide an inorganic light-emitting display apparatus capable of display the image at a low gray-scale level, an inorganic light-emitting device capable of operating in a low current level is required.

The inventors of the present disclosure have invented an inorganic light-emitting device that can operate at a low current level.

Accordingly, embodiments of the present disclosure are directed to a light-emitting device and a display apparatus including the same that substantially obviate one or more of the problems due to limitations and disadvantages of the related art.

An aspect of the present disclosure is to provide a light-emitting device capable of operating at the low-current level and a display apparatus capable of displaying an image at the low-gray-scale level.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a light-emitting device comprises a light-emitting structure including a first semiconductor layer, an active layer, and a second semiconductor layer; a first electrode connected to the first semiconductor layer; and a second electrode connected to the second semiconductor layer, wherein an energy bandgap of the first semiconductor layer decreases as the first semiconductor layer extends away from the active layer.

In another aspect, a display including an array substrate comprises a thin-film transistor and a first connection electrode connected to the thin-film transistor; a conductive adhesive layer disposed on the first connection electrode; and a light-emitting device disposed on the conductive adhesive layer, wherein the light-emitting device includes: a light-emitting structure including a first semiconductor layer, an active layer, and a second semiconductor layer; a first electrode connected to the first semiconductor layer; and a second electrode connected to the second semiconductor layer, wherein an energy bandgap of the first semiconductor layer decreases as the first semiconductor layer extends away from the active layer.

Details of other embodiments are included in the detailed description and drawings.

According to the embodiments of the present disclosure, a potential barrier between the first electrode and the first semiconductor layer (n-type semiconductor layer) in the light-emitting device may be lowered. As a result, driving voltage and driving current required for electrons to overcome a potential barrier between the first electrode and the first semiconductor layer and be injected into the first semiconductor layer may be lowered. Therefore, the light-emitting device according to embodiments of the present disclosure may operate in a low current level.

The light-emitting device according to embodiments of the present disclosure is capable of operating at a low current level. Thus, the display apparatus in which the light-emitting device according to embodiments of the present disclosure is disposed in each sub-pixel may display an image having a gray-scale at a low current level.

It is to be understood that both the foregoing general description and the following detailed description are exemplary and explanatory and are intended to provide further explanation of the inventive concepts as claimed.

### BRIEF DESCRIPTION OF DRAWINGS

The accompanying drawings, which are included to provide a further understanding of the disclosure and are incorporated in and constitute a part of this application, illustrate embodiments of the disclosure and together with the description serve to explain various principles. In the drawings:

FIG. 1 is a cross-sectional view showing a light-emitting device according to one embodiment of the present disclosure.

FIG. 2 is a cross-sectional view showing a light-emitting device according to another embodiment of the present disclosure.

FIG. 3 shows a I-V curve of each of embodiments of the present disclosure.

FIG. 4 shows internal quantum efficiency of each of embodiments of the present disclosure.

FIG. 5 is a cross-sectional view showing a display apparatus according to one embodiment of the present disclosure.

### DETAILED DESCRIPTION

Advantages and features of the present disclosure, and a method of achieving the advantages and features will become apparent with reference to embodiments described later in detail together with the accompanying drawings. However, the present disclosure is not limited to the embodiments as disclosed below, but may be implemented in various different forms. Thus, these embodiments are set forth only to make the present disclosure complete, and to completely inform the scope of the present disclosure to those of ordinary skill in the technical field to which the present disclosure belongs.

A shape, a size, a ratio, an angle, a number, etc. disclosed in the drawings for describing the embodiments of the present disclosure are exemplary, and the present disclosure is not limited thereto. The same reference numerals refer to the same elements herein. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “including”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of the associated listed items. Expression such as “at least one of” when preceding a list of elements may modify the entire list of elements and may not modify the individual elements of the list. In interpretation of numerical values, an error or tolerance therein may occur even when there is no explicit description thereof.

In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when an element or layer is referred to as being “connected to”, or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like may be disposed “on” or “on a top” of another layer, film, region, plate, or the like, the former may directly contact the latter or still another layer, film, region, plate, or the like may be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like may be disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is indicated.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

The features of the various embodiments of the present disclosure may be partially or entirely combined with each other, and may be technically associated with each other or operate with each other. The embodiments may be implemented independently of each other and may be implemented together in an association relationship.

In interpreting a numerical value, the value is interpreted as including an error range unless there is separate explicit description thereof.

It will be understood that when an element or layer is referred to as being “connected to”, or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

The features of the various embodiments of the present disclosure may be partially or entirely combined with each other, and may be technically associated with each other or operate with each other. The embodiments may be implemented independently of each other and may be implemented together in an association relationship.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, display apparatuses according to embodiments according to the present disclosure will be described in detail with reference to the accompanying drawings.

FIG. 1 is a cross-sectional view showing a light-emitting device according to one embodiment of the present disclosure.

Referring to FIG. 1, a light-emitting device ED1 according to an embodiment of the present disclosure may include a light-emitting structure 120, a passivation layer 125, a first electrode 140, and a second electrode 145. The light-emitting device ED1 may have a vertical structure. A maximum horizontal width of the light-emitting device ED1 may be, for example, 100 μm or smaller. The light-emitting device ED1 may be referred to as a micro-light-emitting diode LED (micro-LED).

The light-emitting structure 120 may include a first semiconductor layer 105, an active layer 110, an electron blocking layer 113, and a second semiconductor layer 115. In one example, the light-emitting structure 120 may have a shape in which a width gradually decreases as the structure 120 extends in a direction from the first semiconductor layer 105 to the second semiconductor layer 115. In this case, a side surface of the light-emitting structure 120 may have an inclination.

The side surface of the light-emitting structure 120 may be covered with the passivation layer 125. The passivation layer 125 may extend along and on a portion of a top surface of the second semiconductor layer 115 and cover the portion of the top surface of the second semiconductor layer 115. The passivation layer 125 may be formed of, for example, an inorganic insulating material such as silicon oxide, silicon nitride, silicon nitride, or aluminum oxide.

The first electrode 140 is connected to the first semiconductor layer 105, and the second electrode 145 is connected to the second semiconductor layer 115. Since the light-emitting device ED1 has a vertical structure, the first electrode 140 may be referred to as a lower electrode and the second electrode 145 may be referred to as an upper electrode. When the first semiconductor layer 105 is an n-type semiconductor layer and the second semiconductor layer 115 is a p-type semiconductor layer, the first electrode 140 may be referred to as an n-side electrode and the second electrode 145 may be referred to as a p-side electrode.

The light-emitting structure 120 may be made of, for example, a group III nitride semiconductor material. However, the present disclosure is not limited thereto.

Each of the first semiconductor layer 105, the active layer 110, the electron blocking layer 113, and the second semiconductor layer 115 of the light-emitting structure 120 may be made of a group III nitride semiconductor material, that is, InₓAl_{y}Ga_{(1-x-y)}N (0≤x<1, 0≤y<1).

The first semiconductor layer 105 may be a layer for supplying electrons to the active layer 110 and may be made of an n-type group III nitride semiconductor material doped with impurities such as silicon (Si), germanium (Ge), selenium (Se), or tellurium (Te). An energy bandgap of the first semiconductor layer 105 may decrease as the first semiconductor layer 105 extends away from the active layer 110. The energy bandgap of the first semiconductor layer 105 may decrease as the first semiconductor layer 105 extends toward the first electrode 140.

For example, the first semiconductor layer 105 may be made of n-type indium gallium nitride (InGaN), that is, n-type InₓGa₍₁₋ₓ₎N (0≤x<1). An indium (In) content in the first semiconductor layer 105 may increase as the first semiconductor layer 105 extends away from the active layer 110.

The energy bandgap of the first semiconductor layer 105 may decrease step by step as the first semiconductor layer 105 extends away from the active layer 110. The indium content in the first semiconductor layer 105 may increase step by step as the first semiconductor layer 105 extends away from the active layer 110.

The first semiconductor layer 105 may include a plurality of layers having different indium contents. For example, the first semiconductor layer 105 includes 7 layers, and the indium content in the first semiconductor layer 105 may increase by 5 at % step by step.

For example, the indium content in a seventh layer 105g disposed closest to the active layer 110 among the seven layers of the first semiconductor layer 105 may be 5 at %, and the content of indium in a sixth layer 105f disposed next closest to the active layer 110 among the seven layers of the first semiconductor layer 105 may be 10 at %. Further, the content of indium in a first layer 105a disposed farthest from the active layer 110 among the seven layers of the first semiconductor layer 105 may be 35 at %. The indium content of the first semiconductor layer 105 is measured based on an amount of an entirety of a group III element.

The first layer 105a of the first semiconductor layer 105 may be made of n-type InₓGa₍₁₋ₓ₎N (x=0.35). The second layer 105b of the first semiconductor layer 105 may be made of n-type InₓGa₍₁₋ₓ₎N (x=0.3). The third layer 105c of the first semiconductor layer 105 may be made of n-type InₓGa₍₁₋ₓ₎N (x=0.25). The fourth layer 105d of the first semiconductor layer 105 may be made of n-type InₓGa₍₁₋ₓ₎N (x=0.2). The fifth layer 105e of the first semiconductor layer 105 may be made of n-type InₓGa₍₁₋ₓ₎N (x=0.15). The sixth layer 105f of the first semiconductor layer 105 may be made of n-type InₓGa₍₁₋ₓ₎N (x=0.1). The seventh layer 105g of the first semiconductor layer 105 may be made of n-type InₓGa₍₁₋ₓ₎N (x=0.05).

The number of the layers included in the first semiconductor layer 105 and the indium contents therein may be designed to be different from those as described above. In addition, the maximum indium content of the layers included in the first semiconductor layer 105 may be determined in consideration of crystal quality or phase separation of the first semiconductor layer 105.

The active layer 110 disposed on the first semiconductor layer 105 may have a multi-quantum well (MQW) structure. The active layer 110 may be a layer that emits light based on combination of electrons and holes. The multi-quantum well structure of the active layer 110 includes a plurality of barrier layers and a plurality of well layers. For example, the plurality of well layers may be made of indium gallium nitride (InGaN) and the plurality of barrier layers may be made of gallium nitride (GaN). The content of indium (In) in the well layer may be designed according to a wavelength of light emitted therefrom. The multi-quantum well structure of the active layer 110 is not limited to the details as described above.

The electron blocking layer 113 disposed on the active layer 110 prevents electrons injected from the first semiconductor layer 105 into the active layer 110 from overflowing into the second semiconductor layer 115. The electron blocking layer 113 may be made of a p-type group III nitride semiconductor material doped with impurities such as magnesium (Mg), zinc (Zn), or beryllium (Be). The electron blocking layer 113 may include, for example, p-type aluminum gallium nitride (AlGaN), that is, p-type Al_{y}Ga_{(1-y)}N (0≤y<1). In one embodiment, the electron blocking layer 113 may be omitted.

The second semiconductor layer 115 disposed on the electron blocking layer 113 may be a layer for injecting holes into the active layer 110 and may be made of a p-type group III nitride semiconductor material doped with impurities such as magnesium (Mg), zinc (Zn), or beryllium (Be). The second semiconductor layer 115 may include, for example, p-type gallium nitride (GaN).

The first electrode 140 may be disposed on a lower surface 105bs of the first semiconductor layer 105, and may be composed of a single layer or a plurality of layers made of at least one metal of nickel (Ni), gold (Au), platinum (Pt), titanium (Ti), aluminum (Al), chromium (Cr), copper (Cu), or an alloy thereof.

As described above, the energy bandgap of the first semiconductor layer 105 may decrease stepwise as the first semiconductor layer 105 extends away from the active layer 110. The first layer 105a of the first semiconductor layer 105 contacting the first electrode 140 has the smallest energy bandgap.

Accordingly, a potential barrier between the first electrode 140 and the first semiconductor layer 105 may be lowered. As a result, driving voltage and driving current required for electrons to overcome a potential barrier between the first electrode 140 and the first semiconductor layer 105 and be injected into the first semiconductor layer 105 may be lowered. Therefore, the light-emitting device ED1 can operate in a low current level.

The second electrode 145 disposed on an upper surface of the second semiconductor layer 115 may be compose of a single layer or a plurality of layers made of at least one metal of nickel (Ni), gold (Au), platinum (Pt), titanium (Ti), aluminum (Al), chromium (Cr), copper (Cu), or an alloy thereof.

An ohmic contact layer may be further disposed between the second semiconductor layer 115 and the second electrode 145. The ohmic contact layer may include a transparent conductive oxide such as ITO (Indium Tin Oxide), IGZO (Indium Gallium Zinc Oxide), or IZO (Indium Zinc Oxide).

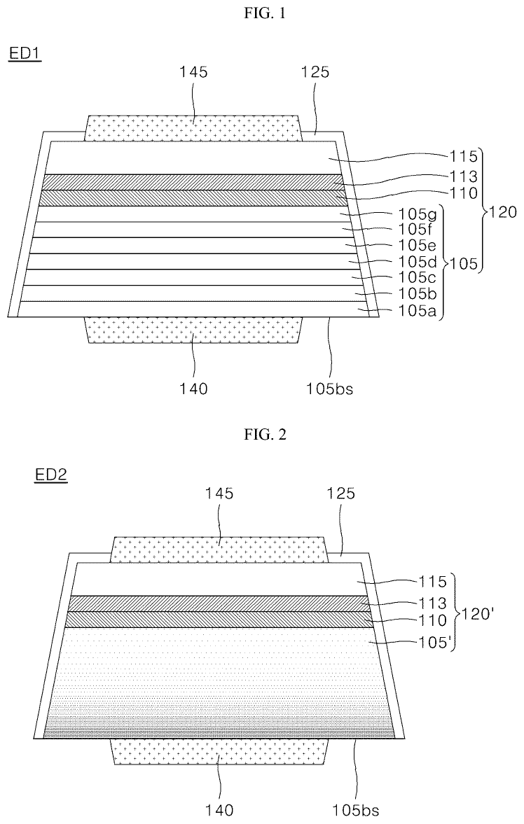

FIG. 2 is a cross-sectional view showing a light-emitting device according to another embodiment of the present disclosure.

Referring to FIG. 2, a light-emitting device ED2 according to another embodiment of the present disclosure may include a light-emitting structure 120′, the passivation layer 125, the first electrode 140, and the second electrode 145. The light-emitting device ED2 may have a vertical structure. A maximum horizontal width of the light-emitting device ED2 may be, for example, 100 μm or smaller. The light-emitting device ED2 may be referred to as a micro-light-emitting diode (Micro-LED).

The light-emitting structure 120′ may include a first semiconductor layer 105′, the active layer 110, the electron blocking layer 113, and the second semiconductor layer 115.

The first semiconductor layer 105′ may be a layer for supplying electrons to the active layer 110, and may be made of an n-type group III nitride semiconductor material doped with impurities such as silicon (Si), germanium (Ge), selenium (Se), or tellurium (Te). An energy bandgap of the first semiconductor layer 105′ may decrease as the first semiconductor layer 105′ extends away from the active layer 110. The energy bandgap of the first semiconductor layer 105′ may decrease as the first semiconductor layer 105′ extends toward the first electrode 140.

For example, the first semiconductor layer 105′ may be made of n-type indium gallium nitride (InGaN), that is, n-type InₓGa₍₁₋ₓ₎N (0≤x<1). The indium (In) content in the first semiconductor layer 105′ may increase as the first semiconductor layer 105′ extends away from the active layer 110.

The energy bandgap of the first semiconductor layer 105′ may decrease linearly or gradually as the first semiconductor layer 105′ extends away from the active layer 110. The indium content in the first semiconductor layer 105′ may linearly or gradually increase as the first semiconductor layer 105′ extends away from the active layer 110. A lower surface 105bs of the first semiconductor layer 105′ in contact with the first electrode 140 may have the highest indium content and may have the smallest energy bandgap.

Accordingly, a potential barrier between the first electrode 140 and the first semiconductor layer 105′ may be lowered. As a result, driving voltage and driving current required for electrons to overcome a potential barrier between the first electrode 140 and the first semiconductor layer 105′ and be injected into the first semiconductor layer 105′ may be lowered. Therefore, the light-emitting device ED2 may operate in a low current level.

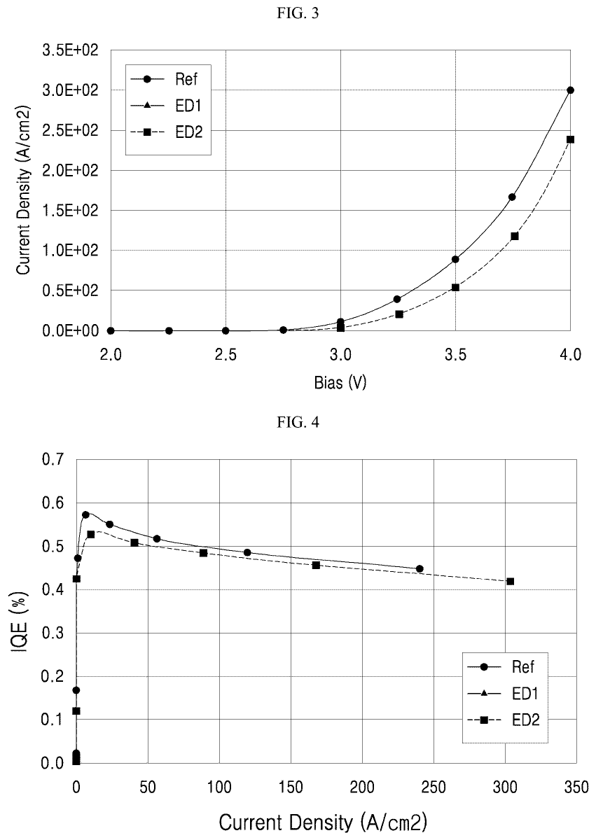

FIG. 3 shows a I-V curve of each of embodiments of the present disclosure. FIG. 4 shows the internal quantum efficiency of each of embodiments of the present disclosure.

A curve marked with ‘Ref’ in each of FIG. 3 and FIG. 4 is directed to Comparative Example. A light-emitting device according to the Comparative Example is the same as each of the first and second embodiments except that the first semiconductor layer is made of n-type GaN.

The curves marked with ‘ED1’ and ‘ED2’ in FIG. 3 and FIG. 4 indicate simulation results of the light-emitting device ED1 as the first embodiment shown in FIG. 1, and the light-emitting device ED2 as the second embodiment shown in FIG. 2, respectively. In FIG. 3 and FIG. 4, the curve of the light-emitting device ED1 overlaps with the curve of the light-emitting device ED2. Therefore, only the curve of the light-emitting device ED2 is shown in FIGS. 3 and 4.

Referring to FIG. 3, it may be identified that each of the light-emitting devices ED1 and ED2 according to the first and second embodiments has lower operation voltage at the same current than that in the light-emitting device Ref according to the Comparative Example. This means that the light-emitting devices ED1 and ED2 according to the first and second embodiments can operate in a lower current level than a current level at which the light-emitting device Ref according to the Comparative Example operates.

Referring to FIG. 4, it may be identified that decrease in the internal quantum efficiency in each of the light-emitting devices ED1 and ED2 according to the first and second embodiments is comparable to decrease in the internal quantum efficiency in the light-emitting device Ref according to the Comparative Example.

In summary, the light-emitting devices ED1 and ED2 according to the first and second embodiments may have the lower operation voltage than that of the light-emitting device Ref according to the Comparative Example, while maintaining a similar level of the internal quantum efficiency to that of the light-emitting device Ref according to the Comparative Example. Therefore, a display apparatus using each of the light-emitting devices ED1 and ED2 according to the first and second embodiments may display an image having a gray-scale level at a low current level.

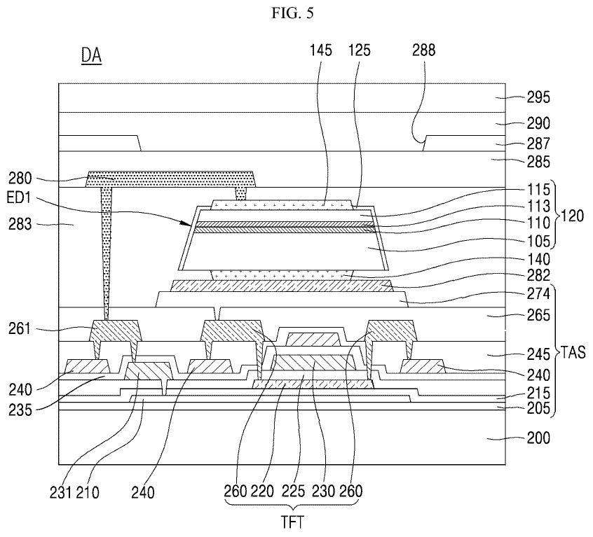

FIG. 5 is a cross-sectional view showing a display apparatus according to one embodiment of the present disclosure. FIG. 5 includes a cross-sectional structure of one sub-pixel of a display apparatus DA according to one embodiment of the present disclosure.

Referring to FIG. 5, a display apparatus DA according to an embodiment of the present disclosure includes an array substrate TAS and the light-emitting device ED1 mounted on the array substrate TAS. FIG. 5 shows that the light-emitting device ED1 as shown in FIG. 1 is mounted on the array substrate TAS. However, the light-emitting device ED2 as shown in FIG. 2 may be mounted thereon. The light-emitting device ED1 may be mounted onto the array substrate TAS in a transfer process.

A pixel driving circuit for driving the light-emitting device ED1 may be included in the array substrate TAS. For example, the array substrate TAS may include a base substrate 200, and a thin-film transistor TFT, a line, and an electrode disposed on the base substrate 200.

The thin-film transistor TFT may include a semiconductor layer 220 formed on the base substrate 200, a gate electrode 230 located on the semiconductor layer 220, a gate insulating layer 225 between the semiconductor layer 220 and the gate electrode 230, and a source/drain electrode 260.

A buffer layer 205 and a light-blocking layer 210 may be disposed between the base substrate 200 and the semiconductor layer 220. However, the present disclosure is not limited thereto.

The buffer layer 205 may prevent diffusion of impurities or moisture from the base substrate 200 toward the thin-film transistor TFT, and may include an inorganic insulating material. In one example, the buffer layer 205 may include silicon nitride or silicon oxide. The buffer layer 205 may be formed as a single layer or a stack of multiple layers.

For example, when the semiconductor layer 220 includes a metal oxide semiconductor, the light-blocking layer 210 serves to prevent light from being introduced into the semiconductor layer 220. A size of the light-blocking layer 210 is preferably larger than that of the semiconductor layer 220 such that the light-blocking layer 210 entirely cover the semiconductor layer 220. The light-blocking layer 210 may be composed of a single layer or a stack of multiple layers including at least one of titanium (Ti), molybdenum (Mo), copper (Cu), aluminum (Al), silver (Ag), chromium (Cr), gold (Au), neodymium (Nd), or nickel (Ni).

A first interlayer insulating layer 215 may be disposed between the buffer layer 205, the light-blocking layer 210, and the semiconductor layer 220.

The gate electrode 230 may be disposed on the gate insulating layer 225 so as to overlap the semiconductor layer 220. A first interlayer connection electrode 231 spaced apart from the gate electrode 230 may be disposed on the gate insulating layer 225. The first interlayer connection electrode 231 may be connected to the light-blocking layer 210 via a first interlayer connection portion 232 extending through the gate insulating layer 225 and the first interlayer insulating layer 215.

A second interlayer insulating layer 235 and a third interlayer insulating layer 245 may be sequentially disposed on the gate electrode 230 and the first interlayer connection electrode 231.

A plurality of connection lines 240 may be disposed on the second interlayer insulating layer 235 and may be covered with the third interlayer insulating layer 245. The source/drain electrode 260 and a second interlayer connection electrode 261 may be disposed on the third interlayer insulating layer 245.

One side of the source/drain electrode 260 may extend through the third interlayer insulating layer 245, the second interlayer insulating layer 235, and the gate insulating layer 225 and then may be connected to the semiconductor layer 220. In addition, the other side of the source/drain electrode 260 may extend through the third interlayer insulating layer 245 and then may be connected to the connection line 240.

One side of the second interlayer connection electrode 261 may extend through the third interlayer insulating layer 245 and the second interlayer insulating layer 235 and then be connected to the first interlayer connection electrode 231. The other side of the second interlayer connection electrode 261 may extend through the third interlayer insulating layer 245 and then be connected to another connection line 240.

A first planarization layer 265 is disposed on the third interlayer insulating layer 245. The first planarization layer 265 may cover the source/drain electrode 260 of the thin-film transistor TFT.

A first connection electrode 274 is disposed on the first planarization layer 265. The first connection electrode 274 may extend through the first planarization layer 265 and be electrically connected to the source/drain electrode 260 of the thin-film transistor TFT.

A conductive adhesive layer 282 is disposed on the first connection electrode 274. The conductive adhesive layer 282 may be a layer for mounting the light-emitting device ED1 on the substrate TAS and may include a conductive material having adhesiveness.

The light-emitting device ED1 is disposed on the conductive adhesive layer 282.

A side surface of the light-emitting device ED1 may be surrounded with a first insulating layer 283. The first insulating layer 283 may cover an upper surface of the light-emitting device ED1. The first insulating layer 283 may cover a side surface of each of the first connection electrode 274 and the adhesive layer 282. The first insulating layer 283 may include, for example, a photosensitive organic material.

A second connection electrode 280 is disposed on the first insulating layer 283. One side of the second connection electrode 280 may extend through the first insulating layer 283 and be connected to the second electrode 145 of the light-emitting device ED1. The other side of the second connection electrode 280 may extend through the first insulating layer 283 and the first planarization layer 265 and be connected to the second interlayer connection electrode 261.

The second interlayer connection electrode 261 may be connected to the light-blocking layer 210 via the first interlayer connection electrode 231.

A second insulating layer 285 may be disposed on the first insulating layer 283. The second insulating layer 285 may include, for example, a photosensitive organic material.

A bank 287 having a bank hole 288 defined therein may be disposed on the second insulating layer 285. In one example, the bank 287 may include a black matrix. Embodiments of the present disclosure are not limited thereto. A second planarization layer 290 is disposed on the bank 287. The second planarization layer 290 may cover a step caused by the bank 287 and the bank hole 288 to provide a flat upper surface. In one example, the second planarization layer 290 may include, for example, a photosensitive organic material.

A cover layer 295 may be disposed on the second planarization layer 290. The cover layer 295 may include a functional optical film such as an anti-scattering film.

As described above, the potential barrier between the first electrode 140 and each of the first semiconductor layers 105 and 105′ in the light-emitting devices ED1 and ED2 may be lowered. Thus, driving voltage and driving current required for electrons to overcome the potential barrier between the first electrode 140 and each of the first semiconductor layers 105 and 105′ and be injected into each of the first semiconductor layers 105 and 105′ may be lowered.

Therefore, the display apparatus DA in which each of the light-emitting devices ED1 and ED2 capable of operating at low current is disposed in each sub-pixel may be able to display an image having a gray-scale at a low current level.

A light-emitting device and a display apparatus according to embodiments of the present disclosure may be described as follows.

A light-emitting device according to an embodiment of the present disclosure includes a light-emitting structure including a first semiconductor layer, an active layer, and a second semiconductor layer; a first electrode connected to the first semiconductor layer; and a second electrode connected to the second semiconductor layer, wherein an energy bandgap of the first semiconductor layer decreases as the first semiconductor layer extends away from the active layer.

In one implementation of the light-emitting device, the energy bandgap of the first semiconductor layer decreases step by step.

In one implementation of the light-emitting device, the energy bandgap of the first semiconductor layer decreases linearly.

In one implementation of the light-emitting device, the first semiconductor layer includes an n-type nitride semiconductor layer containing indium, wherein a content of indium in the first semiconductor layer increases as the first semiconductor layer extends away from the active layer.

In one implementation of the light-emitting device, the content of indium increases step by step.

In one implementation of the light-emitting device, the content of indium increases linearly.

In one implementation of the light-emitting device, the first semiconductor layer includes an n-type indium gallium nitride (InGaN) layer, wherein a content of indium in the first semiconductor layer increases as the first semiconductor layer extends away from the active layer.

In one implementation of the light-emitting device, the content of indium increases step by step.

In one implementation of the light-emitting device, the content of indium increases linearly.

A display apparatus according to an embodiment of the present disclosure includes an array substrate including a thin-film transistor and a first connection electrode connected to the thin-film transistor; a conductive adhesive layer disposed on the first connection electrode; and a light-emitting device disposed on the conductive adhesive layer, wherein the light-emitting device includes: a light-emitting structure including a first semiconductor layer, an active layer, and a second semiconductor layer; a first electrode connected to the first semiconductor layer; and a second electrode connected to the second semiconductor layer, wherein an energy bandgap of the first semiconductor layer decreases as the first semiconductor layer extends away from the active layer.

In one implementation of the display apparatus, the energy bandgap of the first semiconductor layer decreases step by step.

In one implementation of the display apparatus, the energy bandgap of the first semiconductor layer decreases linearly.

In one implementation of the display apparatus, the first semiconductor layer includes an n-type nitride semiconductor layer containing indium, wherein a content of indium in the first semiconductor layer increases as the first semiconductor layer extends away from the active layer.

In one implementation of the display apparatus, the content of indium increases step by step.

In one implementation of the display apparatus, the content of indium increases linearly.

In one implementation of the display apparatus, the first semiconductor layer includes an n-type indium gallium nitride (InGaN) layer, wherein a content of indium in the first semiconductor layer increases as the first semiconductor layer extends away from the active layer.

In one implementation of the display apparatus, the content of indium increases step by step.

In one implementation of the display apparatus, the content of indium increases linearly.

It will be apparent to those skilled in the art that various modifications and variations can be made in the light-emitting device and the display apparatus including the same of the present disclosure without departing from the technical idea or scope of the disclosure. Thus, it is intended that the present disclosure cover the modifications and variations of this disclosure provided they come within the scope of the appended claims and their equivalents.

What is claimed is:

1. A light-emitting device comprising:
a light-emitting structure including a first semiconductor layer, an active layer, and a second semiconductor layer;
a first electrode connected to the first semiconductor layer; and
a second electrode connected to the second semiconductor layer,
wherein an energy bandgap of the first semiconductor layer decreases as the first semiconductor layer extends away from the active layer.

2. The light-emitting device of claim 1, wherein the energy bandgap of the first semiconductor layer decreases step by step.

3. The light-emitting device of claim 1, wherein the energy bandgap of the first semiconductor layer decreases linearly.

4. The light-emitting device of claim 1, wherein the first semiconductor layer includes an n-type nitride semiconductor layer containing indium, wherein a content of indium in the first semiconductor layer increases as the first semiconductor layer extends away from the active layer.

5. The light-emitting device of claim 4, wherein the content of indium increases step by step.

6. The light-emitting device of claim 4, wherein the content of indium increases linearly.

7. The light-emitting device of claim 1, wherein the first semiconductor layer includes an n-type indium gallium nitride (InGaN) layer, wherein a content of indium in the first semiconductor layer increases as the first semiconductor layer extends away from the active layer.

8. The light-emitting device of claim 7, wherein the content of indium increases step by step.

9. The light-emitting device of claim 7, wherein the content of indium increases linearly.

10. A display apparatus comprising:
an array substrate including a thin-film transistor and a first connection electrode connected to the thin-film transistor;
a conductive adhesive layer disposed on the first connection electrode; and
a light-emitting device disposed on the conductive adhesive layer,
wherein the light-emitting device includes:
a light-emitting structure including a first semiconductor layer, an active layer, and a second semiconductor layer;
a first electrode connected to the first semiconductor layer; and
a second electrode connected to the second semiconductor layer,
wherein an energy bandgap of the first semiconductor layer decreases as the first semiconductor layer extends away from the active layer.

11. The display apparatus of claim 10, wherein the energy bandgap of the first semiconductor layer decreases step by step.

12. The display apparatus of claim 10, wherein the energy bandgap of the first semiconductor layer decreases linearly.

13. The display apparatus of claim 10, wherein the first semiconductor layer includes an n-type nitride semiconductor layer containing indium, wherein a content of indium in the first semiconductor layer increases as the first semiconductor layer extends away from the active layer.

14. The display apparatus of claim 13, wherein the content of indium increases step by step.

15. The display apparatus of claim 13, wherein the content of indium increases linearly.
